(19) United States
(12) Patent Application Publication
(10) Pub. No.: US 2024/0421003 A1
(43) Pub. Date: Dec. 19, 2024

(54) BACKSIDE CONTACTS FOR GATE, SOURCE, AND DRAIN

(71) Applicant: International Business Machines Corporation, Armonk, NY (US)

(72) Inventors: Tsung-Sheng Kang, Ballston Lake, NY (US); Tao Li, Slingerlands, NY (US); Ruilong Xie, Niskayuna, NY (US); Tenko Yamashita, Schenectady, NY (US)

(21) Appl. No.: 18/334,486

(22) Filed: Jun. 14, 2023

(51) Int. Cl. H01L 21/8234; H01L 21/768; H01L 23/528; H01L 27/088; H01L 29/08

(52) U.S. Cl. CPC H01L 21/823475; H01L 21/76834; H01L 23/5286; H01L 27/088; H01L 29/0847

(57) ABSTRACT

Embodiments of the present invention are directed to processing methods and resulting structures for providing contacts for gate, source, and drain regions through a wafer backside. In a non-limiting embodiment of the invention, a front end of line structure having a gate and a source or drain (S/D) region is formed and a back end of line structure is formed on a first surface of the front end of line structure. The back end of line structure includes a backside S/D contact on a surface of the S/D region, a backside gate contact on a surface of the gate, and a backside contact liner in direct contact with a sidewall of the backside S/D contact and a sidewall of the backside gate contact. The backside gate contact is electrically isolated from the backside S/D contact by the backside contact liner.

### BACKGROUND

The present invention generally relates to fabrication methods and resulting structures for semiconductor devices, and more specifically, to processing methods and resulting structures for providing contacts for gate, source, and drain regions through a wafer backside.

The development of an integrated circuit (i.e., chip) involves several stages from design through fabrication. Many aspects of the development are performed iteratively to ensure that the chip ultimately manufactured meets all design requirements. Defining the chip architecture is one of the earliest phases of integrated circuit development. The power (e.g., power requirement), performance (e.g., timing), and area (i.e., space needed) for the resulting chip, collectively PPA, is one of the primary metrics by which integrated circuits are evaluated. PPA is largely a consequence of the chip architecture.

Semiconductor fabrication continues to evolve towards improving one or more aspects of PPA. For example, a higher number of active devices (mainly transistors) of ever decreasing device dimensions are placed on a given surface of semiconductor material. Density scaling has put a strain on the design and fabrication of the interconnects between the front end of line of the integrated circuit, consisting mainly of the active devices, and the contact terminals of the integrated circuit. In many chip architectures, all of these interconnects are incorporated in the back end of line (BEOL) structure of the integrated circuit, which includes a stack of metallization layers and vertical via connections built on top of the front end of line (FEOL) structure.

A key component of the BEOL structure is the power delivery network (PDN). The PDN of an integrated circuit is defined by the conductors and vias connected to the power supply (VDD) and ground (VSS) terminals of the chip. The PDN is responsible for delivering power to the individual devices in the front end. The integration of the PDN in the BEOL has become particularly challenging as device densities continue to scale. Backside power delivery is one known solution to this problem, and involves moving some (or most, or all) layers of the PDN from the front side of the integrated circuit to the back side. In a backside-style architecture, the repositioned layers are not formed on top of the FEOL, but are instead formed on the opposite side of the chip (i.e., on the backside of the semiconductor substrate onto which the active devices have been built).

### SUMMARY

Embodiments of the invention are directed to a method for providing contacts for gate, source, and drain regions through a wafer backside. A non-limiting example of the method includes forming a front end of line structure having a gate and a source or drain (S/D) region and forming a back end of line structure on a first surface of the front end of line structure. The back end of line structure includes a backside S/D contact on a surface of the S/D region, a backside gate contact on a surface of the gate, and a backside contact liner in direct contact with a sidewall of the backside S/D contact and a sidewall of the backside gate contact. The backside gate contact is electrically isolated from the backside S/D contact by the backside contact liner.

Embodiments of the invention are directed to a semiconductor structure. A non-limiting example of the semiconductor structure includes a front end of line structure comprising a gate and a S/D region. The front end of line structure further includes a first buffer layer and a second buffer layer below a bottom dielectric layer (BDI). A back end of line structure is formed on a first surface of the front end of line structure. The back end of line structure includes a backside S/D contact on a surface of the S/D region, a backside gate contact on a surface of the gate, and a backside contact liner in direct contact with a sidewall of the backside S/D contact and a sidewall of the backside gate contact.

Embodiments of the invention are directed to a semiconductor structure. A non-limiting example of the semiconductor structure includes a front end of line structure having a gate and a S/D region and a back end of line structure on a first surface of the front end of line structure. The front end of line structure further includes a first buffer layer and a second buffer layer below a BDI. The back end of line structure includes a backside S/D contact on a surface of the S/D region, a backside S/D cap on a surface of the backside S/D contact opposite the S/D region, a backside power rail on the surface of the backside S/D contact, a backside gate contact on a surface of the gate, and a backside signal rail on the backside gate contact. The backside power rail is electrically isolated from the backside gate contact and the backside signal rail by the backside S/D cap.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1A depicts a cross-sectional view taken along the line X1 (across gate in channel region) in FIG. 1E of a semiconductor wafer after an initial set of processing operations according to one or more embodiments of the invention;

FIG. 1B depicts a cross-sectional view taken along the line X2 (across gate out of channel) in FIG. 1E of the semiconductor wafer after the initial set of processing operations according to one or more embodiments of the invention;

FIG. 1C depicts a cross-sectional view taken along the line Y1 (along gate in channel region) in FIG. 1E of the semiconductor wafer after the initial set of processing operations according to one or more embodiments of the invention;

FIG. 1D depicts a cross-sectional view taken along the line Y2 (across channel in source/drain region) in FIG. 1E of the semiconductor wafer after the initial set of processing operations according to one or more embodiments of the invention;

FIG. 1E depicts a top-down reference view of the semiconductor wafer in accordance with one or more embodiments;

FIG. 2A depicts the cross-sectional view taken along the line X1 after a processing operation according to one or more embodiments of the invention;

FIG. 2B depicts the cross-sectional view taken along the line X2 after a processing operation according to one or more embodiments of the invention;

FIG. 2C depicts the cross-sectional view taken along the line Y1 after a processing operation according to one or more embodiments of the invention;

FIG. 2D depicts the cross-sectional view taken along the line Y2 after a processing operation according to one or more embodiments of the invention;

FIG. 3A depicts the cross-sectional view taken along the line X1 after a processing operation according to one or more embodiments of the invention;

FIG. 3B depicts the cross-sectional view taken along the line X2 after a processing operation according to one or more embodiments of the invention;

FIG. 3C depicts the cross-sectional view taken along the line Y1 after a processing operation according to one or more embodiments of the invention;

FIG. 3D depicts the cross-sectional view taken along the line Y2 after a processing operation according to one or more embodiments of the invention;

FIG. 4A depicts the cross-sectional view taken along the line X1 after a processing operation according to one or more embodiments of the invention;

FIG. 4B depicts the cross-sectional view taken along the line X2 after a processing operation according to one or more embodiments of the invention;

FIG. 4C depicts the cross-sectional view taken along the line Y1 after a processing operation according to one or more embodiments of the invention;

FIG. 4D depicts the cross-sectional view taken along the line Y2 after a processing operation according to one or more embodiments of the invention;

FIG. 5A depicts the cross-sectional view taken along the line X1 after a processing operation according to one or more embodiments of the invention;

FIG. 5B depicts the cross-sectional view taken along the line X2 after a processing operation according to one or more embodiments of the invention;

FIG. 5C depicts the cross-sectional view taken along the line Y1 after a processing operation according to one or more embodiments of the invention;

FIG. 5D depicts the cross-sectional view taken along the line Y2 after a processing operation according to one or more embodiments of the invention;

FIG. 6A depicts the cross-sectional view taken along the line X1 after a processing operation according to one or more embodiments of the invention;

FIG. 6B depicts the cross-sectional view taken along the line X2 after a processing operation according to one or more embodiments of the invention;

FIG. 6C depicts the cross-sectional view taken along the line Y1 after a processing operation according to one or more embodiments of the invention;

FIG. 6D depicts the cross-sectional view taken along the line Y2 after a processing operation according to one or more embodiments of the invention;

FIG. 7A depicts the cross-sectional view taken along the line X1 after a processing operation according to one or more embodiments of the invention;

FIG. 7B depicts the cross-sectional view taken along the line X2 after a processing operation according to one or more embodiments of the invention;

FIG. 7C depicts the cross-sectional view taken along the line Y1 after a processing operation according to one or more embodiments of the invention;

FIG. 7D depicts the cross-sectional view taken along the line Y2 after a processing operation according to one or more embodiments of the invention;

FIG. 8A depicts the cross-sectional view taken along the line X1 after a processing operation for forming a first structure according to one or more embodiments of the invention;

FIG. 8B depicts the cross-sectional view taken along the line X2 after a processing operation for forming the first structure according to one or more embodiments of the invention;

FIG. 8C depicts the cross-sectional view taken along the line Y1 after a processing operation for forming the first structure according to one or more embodiments of the invention;

FIG. 8D depicts the cross-sectional view taken along the line Y2 after a processing operation for forming the first structure according to one or more embodiments of the invention;

FIG. 9A depicts the cross-sectional view taken along the line X1 after a processing operation for forming a second structure according to one or more embodiments of the invention;

FIG. 9B depicts the cross-sectional view taken along the line X2 after a processing operation for forming the second structure according to one or more embodiments of the invention;

FIG. 9C depicts the cross-sectional view taken along the line Y1 after a processing operation for forming the second structure according to one or more embodiments of the invention;

FIG. 9D depicts the cross-sectional view taken along the line Y2 after a processing operation for forming the second structure according to one or more embodiments of the invention;

FIG. 10A depicts the cross-sectional view taken along the line X1 after a processing operation for forming the second structure according to one or more embodiments of the invention;

FIG. 10B depicts the cross-sectional view taken along the line X2 after a processing operation for forming the second structure according to one or more embodiments of the invention;

FIG. 10C depicts the cross-sectional view taken along the line Y1 after a processing operation for forming the second structure according to one or more embodiments of the invention;

FIG. 10D depicts the cross-sectional view taken along the line Y2 after a processing operation for forming the second structure according to one or more embodiments of the invention; and

FIG. 11 depicts a flow diagram illustrating a method according to one or more embodiments of the invention.

The diagrams depicted herein are illustrative. There can be many variations to the diagram or the operations described therein without departing from the spirit of the invention. For instance, the actions can be performed in a differing order or actions can be added, deleted or modified.

In the accompanying figures and following detailed description of the described embodiments of the invention, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the invention are described in connection with a particular transistor architecture, embodiments of the invention are not limited to the particular transistor architectures or materials described in this specification. Rather, embodiments of the present invention are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present invention, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

As discussed previously, a key component of the BEOL structure is the power delivery network (PDN). Backside power delivery, also referred to as a backside power delivery network (BSPDN), is a chip architecture that involves repositioning layers of the PDN from the top of the FEOL to the opposite side of the chip to free space on the front side for additional elements (e.g., more transistors). In other words, in a backside-style architecture the PDN layers are placed on the backside of the semiconductor substrate onto which the active devices have been built.

Backside-style architecture require one or more so-called backside contacts to provide electrical continuity to various structures (e.g., gate, source, drain) of the device. Placing these backside contacts can be difficult due to poor margins and access. For example, placing non-self-aligned backside contacts is especially challenging when there is gate backside via for signal routing. A self-aligned backside contact can be used to mitigate poor overlay margins at the wafer backside, but placing self-aligned backside contacts introduces new, often challenging, modules to the fabrication process. Some backside integration modules include, for example, placeholder formation, backside silicon removal selective to the placeholder, etc.

Turning now to an overview of aspects of the present invention, one or more embodiments of the invention address the above-described shortcomings by providing new fabrication methods and resulting structures for providing contacts for gate, source, and drain regions through a wafer backside. In some embodiments, additional sacrificial layers (e.g., sacrificial SiGe) are formed under the bottom dielectric isolation (BDI). Post-wafer flip, these additional sacrificial layers serve as buffer layers so that remaining silicon can be removed without damaging the source/drain epitaxy or gate (e.g., high-k metal gate), even if the BDI has a pin hold. Once the remaining silicon is removed, the backside dielectrics (e.g., backside ILD) can be formed without device damage. The additional sacrificial layers also provide additional process margin for source/drain contact patterning.

In some embodiments, a backside source/drain contact sidewall is covered with dielectric liner. In this manner, a backside gate contact can be isolated from the backside source/drain contact.

In some embodiments, a dielectric cap layer is placed over a backside source/drain contact. In this manner, a backside power rail can be isolated from a backside gate contact and from a backside signal rail.

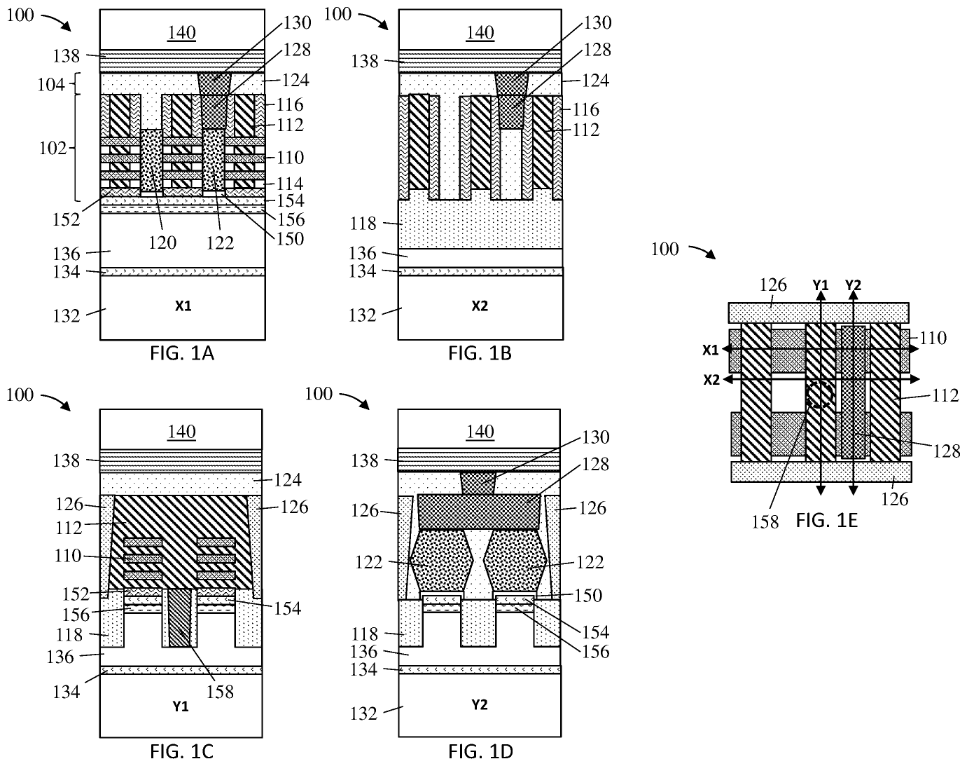

Turning now to a more detailed description of fabrication operations and resulting structures according to aspects of the invention, FIG. 1A depicts a cross-sectional view taken along the line X1 (across gate in channel region) in FIG. 1E of a semiconductor wafer 100 after an initial set of fabrication operations have been applied as part of a method of fabricating a final semiconductor device according to one or more embodiments of the invention. FIG. 1B depicts a cross-sectional view taken along the line X2 (across gate out of channel) in FIG. 1E. FIG. 1C depicts a cross-sectional view taken along the line Y1 (along gate in channel region) in FIG. 1E. FIG. 1D depicts a cross-sectional view taken along the line Y2 (across channel in source/drain region) in FIG. 1E. FIG. 1E depicts a top-down reference view of the semiconductor wafer 100.

As shown in FIGS. 1A-1E, various FEOL structures 102 and MOL structures 104 have been built in the semiconductor wafer 100. The specific examples of the FEOL structures 102 and MOL structures 104 are provided for ease of discussion only and are not meant to be particularly limited. For example, the FEOL structures 102 illustrate a nanosheet-style transistor architecture. It should be understood, however, that the nanosheet-style transistor architecture of the FEOL structures 102 is provided for ease of discussion only and that other transistor architectures (e.g., vertical tunneling transistors, planar transistors, finFETs, etc.) are included in the contemplated scope of this disclosure. Similarly, other MOL structures can be fabricated depending on the needs of a given application, and all such configurations are within the contemplated scope of this disclosure.

In some embodiments, the semiconductor wafer 100 includes one or more nanosheets 110 (collectively, a nanosheet stack(s)) and a gate 112 formed over channel regions of the one or more nanosheets 110. As used herein, a “channel region” refers to the portion of a nanosheet of the one or more nanosheets 110 over which the gate 112 is formed, and through which current passes from source to drain in the final device.

The semiconductor wafer 100 can include various additional FEOL structures, such as, for example, inner spacers 114, gate spacers 116, a shallow trench isolation (STI) region 118, first S/D regions 120, second S/D regions 122, interlayer dielectrics 124, and gate cut 126, and MOL structures, such as, for example, S/D contacts 128 and S/D vias 130, configured and arranged as shown.

In some embodiments, semiconductor wafer 100 can include additional structures, such as, for example, a silicon buffer epitaxy 150, a bottom dielectric isolation (BDI) 152, a first sub-BDI buffer layer 154, a second sub-BDI buffer layer 156, and a backside gate cap 158, configured and arranged as shown.

The first sub-BDI buffer layer 154 and the second sub-BDI buffer layer 156 are so named due to their relative locations below the BDI 152. The first sub-BDI buffer layer 154 and the second sub-BDI buffer layer 156 can also be referred to as a first buffer semiconductor layer and a second buffer semiconductor layer, respectively. Observe further that the first sub-BDI buffer layer 154 and the second sub-BDI buffer layer 156 only exist below the first S/D regions 120 and the second S/D regions 122 (i.e., these structures are sub-S/D as well). While shown having two buffer layers (i.e., the first sub-BDI buffer layer 154 and the second sub-BDI buffer layer 156), the semiconductor wafer 100 can include any number of these buffer layers (e.g., 3, 4, 5, 10, etc.) and all such configurations are within the contemplated scope of this disclosure.

In some embodiments, the first sub-BDI buffer layer 154 and the second sub-BDI buffer layer 156 are formed from materials selected to provide mutual etch selectivity. For example, in embodiments where the first sub-BDI buffer layer 154 and the second sub-BDI buffer layer 156 are silicon germanium layers, the first sub-BDI buffer layer 154 can include a germanium concentration that is lower than the germanium concentration in the second sub-BDI buffer layer 156. For example, if the first sub-BDI buffer layer 154 includes a germanium concentration of 30 percent (sometimes referred to as SiGe30), the second sub-BDI buffer layer 156 can include a germanium concentration of 55 percent (SiGe55), although other germanium concentrations are within the contemplated scope of this disclosure.

In some embodiments, the semiconductor wafer 100 includes a substrate 132 having an etch stop layer 134 (e.g., a buried oxide layer or a SiGe epi layer) and an additional semiconductor layer 136 (e.g., Si) over the etch stop layer 134, although other substrate configurations are within the contemplated scope of this disclosure. In some embodiments, the substrate (e.g., substrate 132/134/136) includes a silicon-on-insulator (SOI) structure and the substrate 132 is a bottommost substrate layer.

In some embodiments, BEOL structures 138 are formed over the MOL structures 104. The BEOL structures 138 are not meant to be particularly limited and can include, for example, various vias (e.g., “V0”, “V1”), metal layers (e.g., “M1”, “M2”), and any number of intermediate interconnects (metal levels/vias between Mx and Mx+1).

In some embodiments, a carrier wafer 140 is formed over the BEOL structures 138. The carrier wafer 140 can be made of a same or different material as the substrate 132/134/136, such as a wafer handling material.

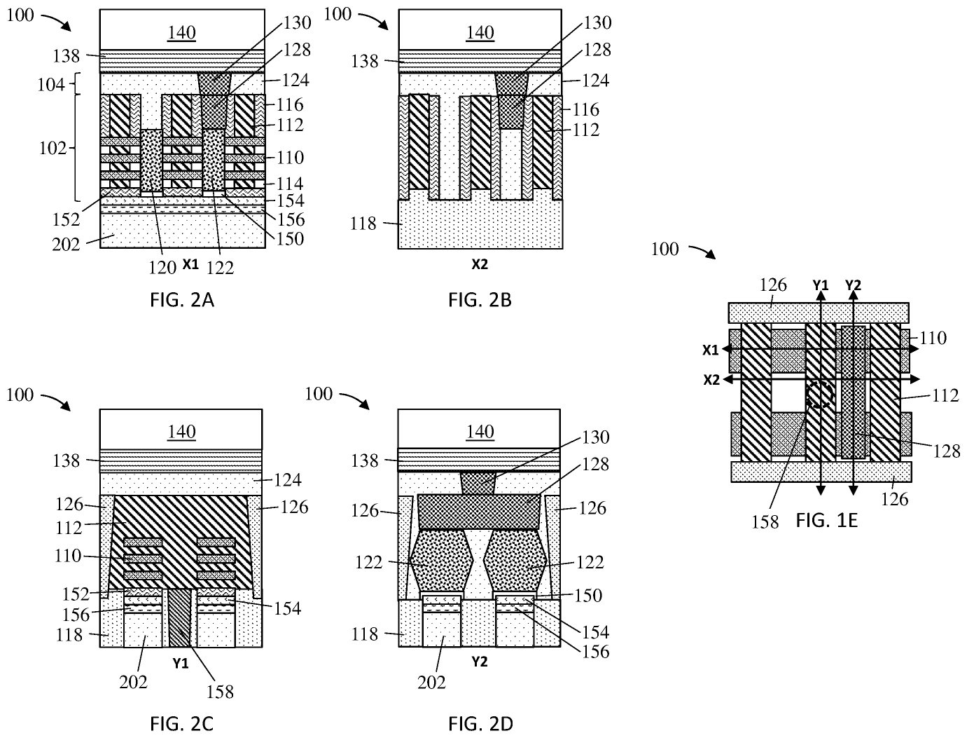

FIGS. 2A, 2B, 2C, and 2D, depict cross-sectional views of the semiconductor wafer 100 taken along the lines X1, X2, Y1, and Y2, respectively, of FIG. 1E after a processing operation according to one or more embodiments. As shown in FIGS. 2A, 2C, and 2D, a backside dielectric 202 (backside ILD) is formed below the first sub-BDI buffer layer 154 and the second sub-BDI buffer layer 156.

In some embodiments, the backside dielectric 202 is formed using a wafer flip process whereby the semiconductor wafer 100 is flipped and the substrate 132 is removed. The substrate 132 can be removed using any suitable technique, such as grinding and/or chemical-mechanical planarization (CMP) to the etch stop layer 134 (i.e., stopping on the etch stop).

In some embodiments, the etch stop layer 134 and the additional semiconductor layer 136 are removed. In some embodiments, the backside dielectric 202 is formed by replacing portions of the removed additional semiconductor layer 136 with dielectric material.

Notably, the first sub-BDI buffer layer 154 and the second sub-BDI buffer layer 156 serve as a buffer layer during this process, and the additional semiconductor layer 136 (e.g., silicon) can be removed without exposing and/or damaging the first S/D regions 120, the second S/D regions 122, the gate 112, and the BDI 152 (e.g., in cases where the BDI has a pin hold).

In some embodiments, the backside dielectric 202 is planarized using, for example, CMP. In some embodiments, the backside dielectric 202 is planarized to the backside gate cap 158 (e.g., CMP stop on gate cap).

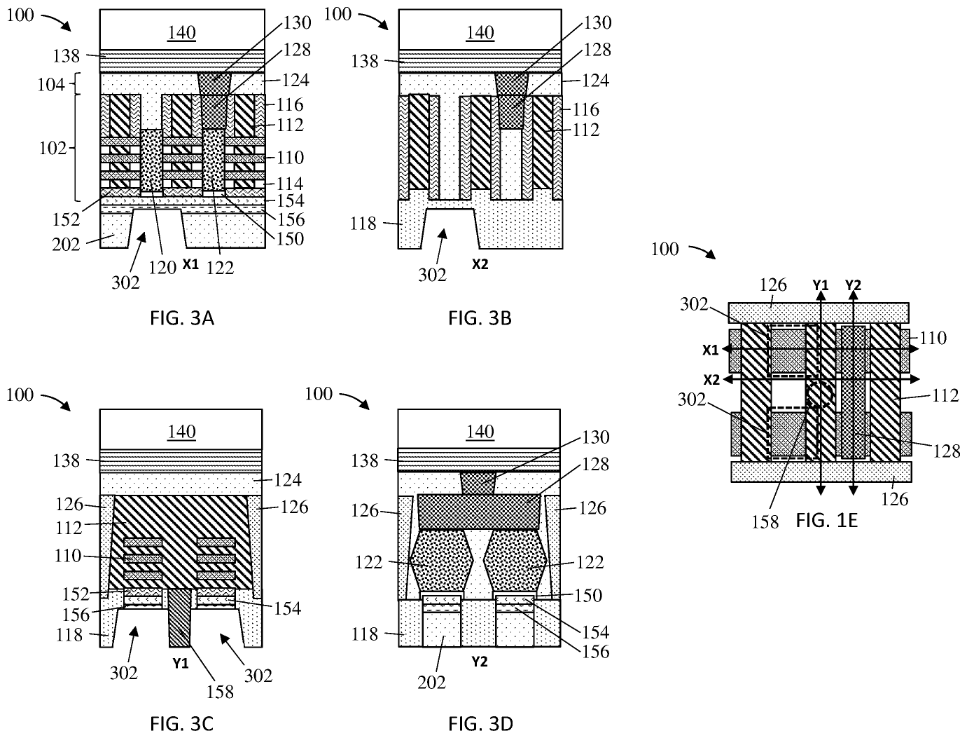

FIGS. 3A, 3B, 3C, and 3D, depict cross-sectional views of the semiconductor wafer 100 taken along the lines X1, X2, Y1, and Y2, respectively, of FIG. 1E after a processing operation according to one or more embodiments. As shown in FIGS. 3A, 3B, and 3C, one or more backside source/drain contact patterns (trenches) 302 can be formed opposite the first S/D regions 120. The backside source/drain contact patterns 302 can be formed using any suitable technique, such as, for example, using a wet etch, a dry etch, or a combination of sequential wet and/or dry etches.

Notably, process margins on the backside source/drain contact patterns 302 are relaxed, as the backside source/drain contact patterns 302 can land anywhere in the first sub-BDI buffer layer 154 and/or the second sub-BDI buffer layer 156 without defects/shorting. In other words, the backside source/drain contact patterns 302 need not land on the relatively thin BDI 152 due to the presence of the first sub-BDI buffer layer 154 and the second sub-BDI buffer layer 156. The result is a relatively larger process window (relaxing of critical dimension limits), offering, in some embodiments, an overlay as large as 10 to 15 nanometers at the 7 nm technology node (similar benefits are realized above and below the 7 nm node). Moreover, the backside gate cap 158 serves as a stop to enable a self-aligned backside S/D open process (i.e., with respect to the later backside gate via). As shown, the backside source/drain contact patterns 302 lands in the second sub-BDI buffer layer 156.

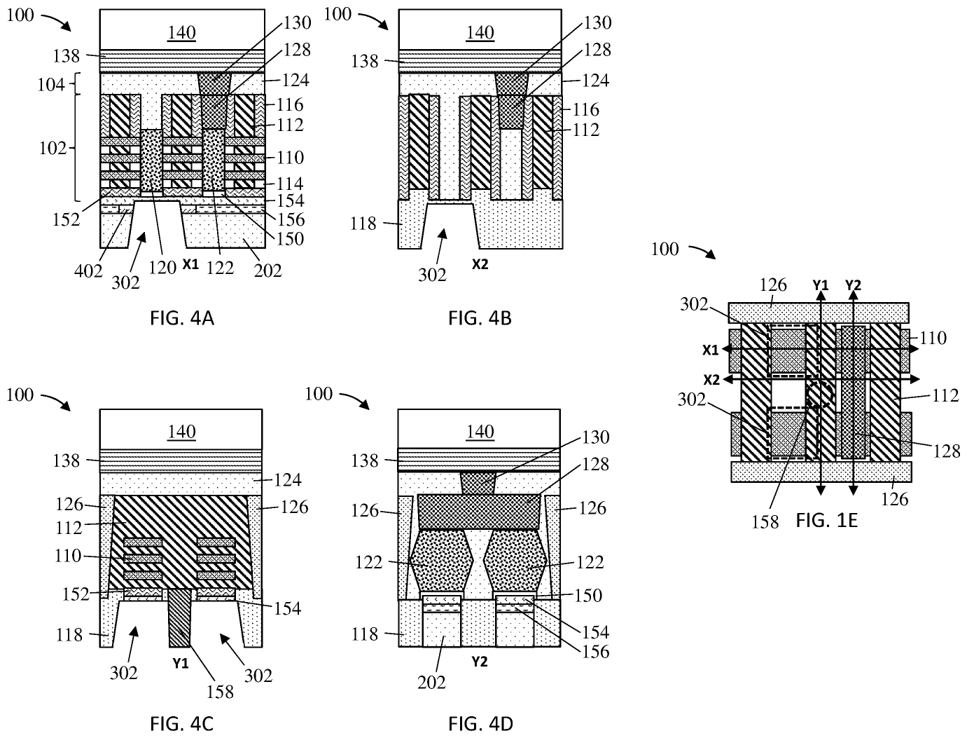

FIGS. 4A, 4B, 4C, and 4D, depict cross-sectional views of the semiconductor wafer 100 taken along the lines X1, X2, Y1, and Y2, respectively, of FIG. 1E after a processing operation according to one or more embodiments. As shown in FIGS. 4A, 4B, and 4C, the one or more backside source/drain contact patterns 302 are extended (deepened) into the first sub-BDI buffer layer 154. The backside source/drain contact patterns 302 can be deepened using any suitable technique, such as, for example, using a wet etch, a dry etch, or a combination of sequential wet and/or dry etches.

In some embodiments, a backside inner spacer 402 is formed in the second sub-BDI buffer layer 156. In some embodiments, the backside inner spacer 402 is embedded (as an indentation) into the second sub-BDI buffer layer 156. In some embodiments, portions of the second sub-BDI buffer layer 156 are removed (e.g., recessed) and replaced with the backside inner spacer 402. In some embodiments, portions of the second sub-BDI buffer layer 156 are removed selective to the first sub-BDI buffer layer 154 and/or the backside dielectric 202. The backside inner spacer 402 can be made of any suitable dielectric material, such as, for example, but are not limited to, SiO2, SiN, SiC, SiOC, SiBCN, SiOCN, or combinations of these materials.

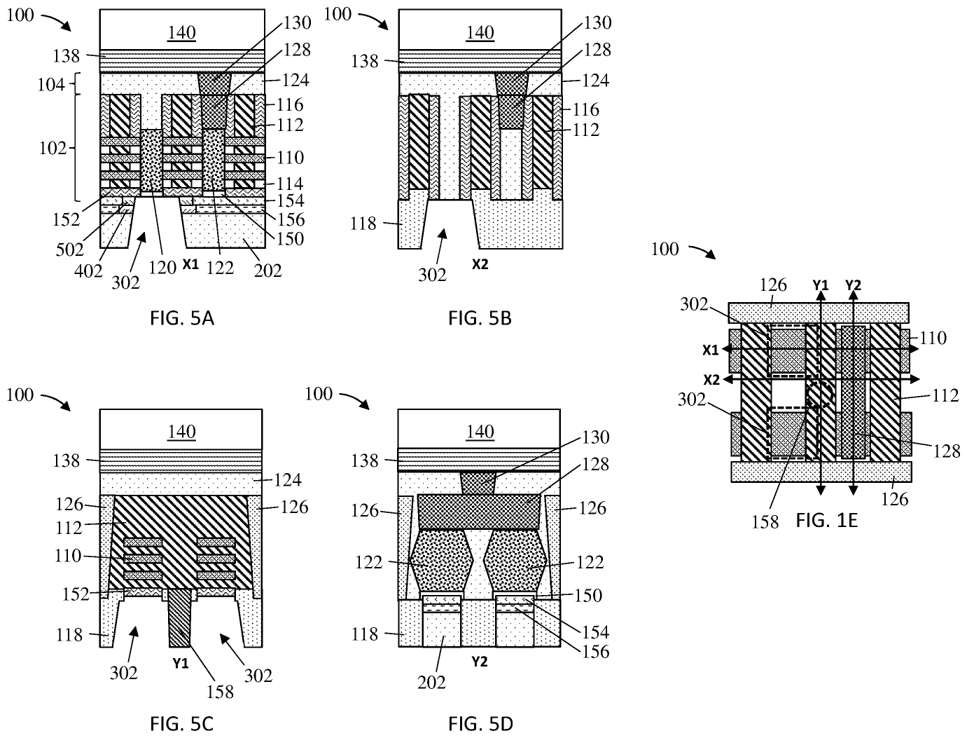

FIGS. 5A, 5B, 5C, and 5D, depict cross-sectional views of the semiconductor wafer 100 taken along the lines X1, X2, Y1, and Y2, respectively, of FIG. 1E after a processing operation according to one or more embodiments. As shown in FIGS. 5A, 5B, and 5C, the one or more backside source/drain contact patterns 302 are extended (deepened) to the surface of the BDI 152. The backside source/drain contact patterns 302 can be deepened using any suitable technique, such as, for example, using a wet etch, a dry etch, or a combination of sequential wet and/or dry etches.

In some embodiments, a backside inner spacer 502 is formed in the first sub-BDI buffer layer 154. The backside inner spacer 502 can be formed in a similar manner as discussed with respect to the backside inner spacer 402 in the second sub-BDI buffer layer 156. In some embodiments, the backside inner spacer 502 is embedded (as an indentation) into the first sub-BDI buffer layer 154. In some embodiments, portions of the first sub-BDI buffer layer 154 are removed (e.g., recessed) and replaced with the backside inner spacer 502. In some embodiments, portions of the first sub-BDI buffer layer 154 are removed selective to the BDI 152, silicon buffer epitaxy 150, and/or backside inner spacer 402. The backside inner spacer 502 can be made of any suitable dielectric material, such as, for example, but are not limited to, SiO2, SiN, SiC, SiOC, SiBCN, SiOCN, or combinations of these materials. Note that, while the semiconductor wafer 100 is shown having two pairs of backside inner spacers (i.e., the backside inner spacer 402 and the backside inner spacer 502), the semiconductor wafer 100 can include any number of these backside inner spacers, depending on the number of buffer layers (e.g., a pair of backside inner spacers is formed for each buffer layer), and all such configurations are within the contemplated scope of this disclosure.

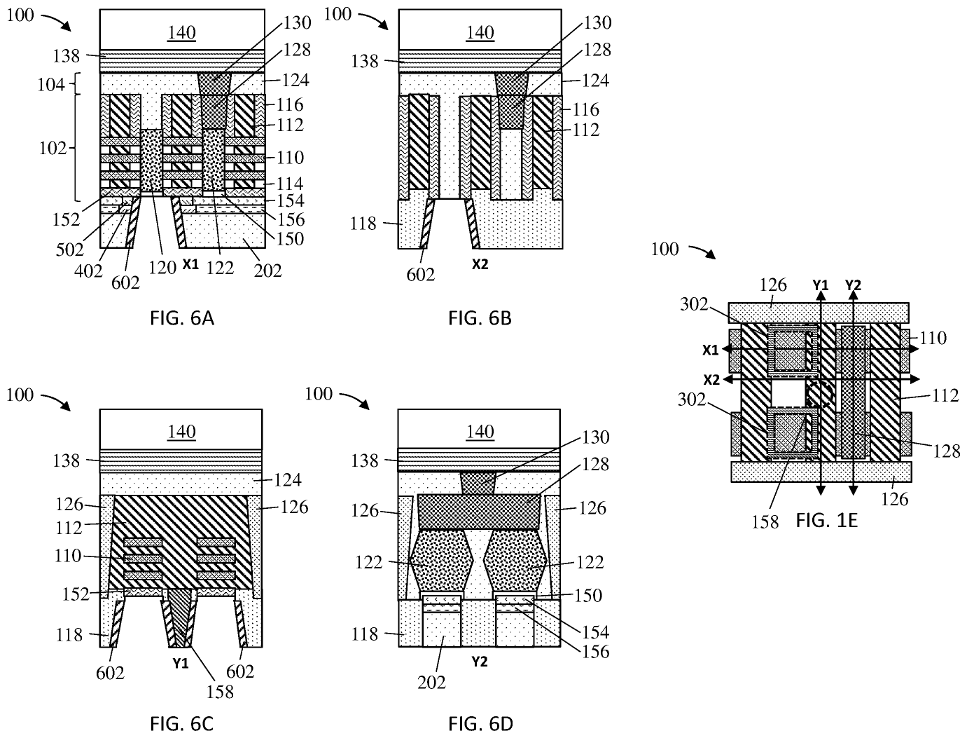

FIGS. 6A, 6B, 6C, and 6D, depict cross-sectional views of the semiconductor wafer 100 taken along the lines X1, X2, Y1, and Y2, respectively, of FIG. 1E after a processing operation according to one or more embodiments. As shown in FIGS. 6A, 6B, and 6C, a backside contact liner 602 is formed in the backside source/drain contact patterns 302. In some embodiments, the backside contact liner 602 is formed by conformally depositing dielectric liner material into the backside source/drain contact patterns 302 and breaking through. In some embodiments, breaking through includes removing a portion of the backside contact liner 602 to expose the BDI 152 and the silicon buffer epitaxy 150.

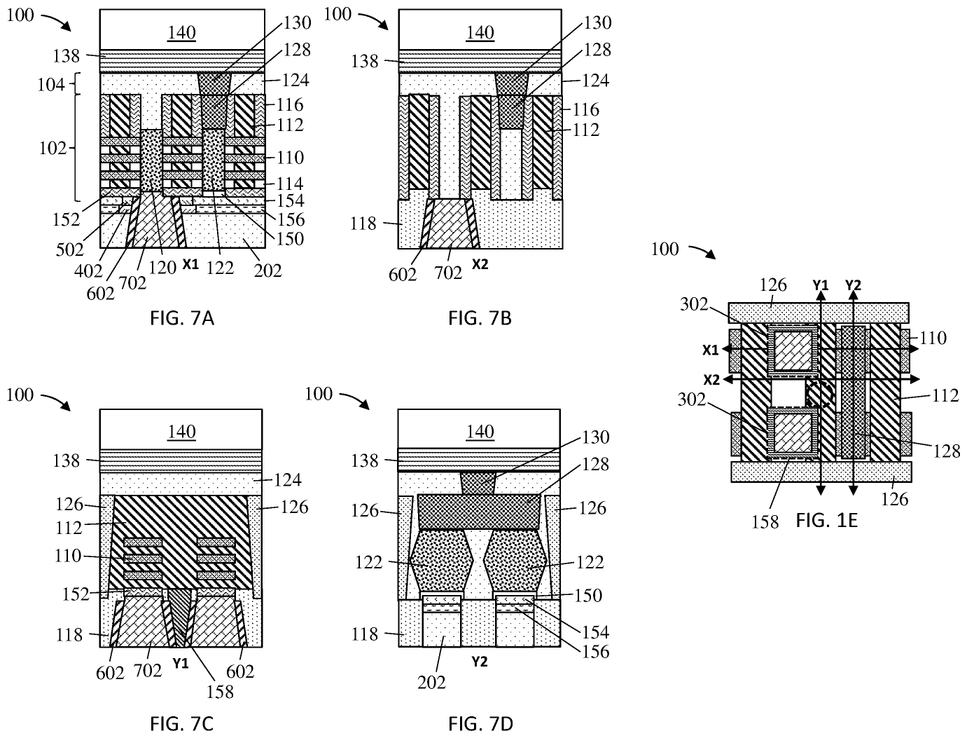

FIGS. 7A, 7B, 7C, and 7D, depict cross-sectional views of the semiconductor wafer 100 taken along the lines X1, X2, Y1, and Y2, respectively, of FIG. 1E after a processing operation according to one or more embodiments. As shown in FIGS. 7A, 7B, and 7C, one or more backside S/D contacts 702 can be formed in the backside source/drain contact patterns 302. The backside S/D contacts 702 can be formed using suitable contact metallization materials, such as, for example, metals, conductive non-metals, and combinations thereof. In some embodiments, the silicon buffer epitaxy 150 is removed prior to contact metallization (as shown).

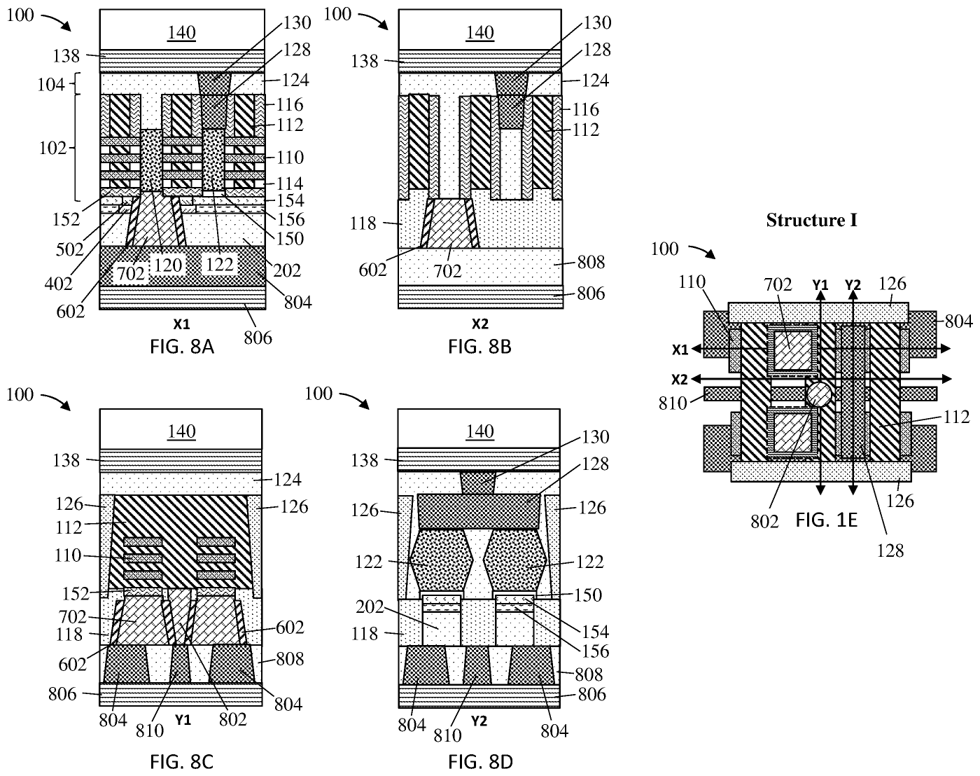

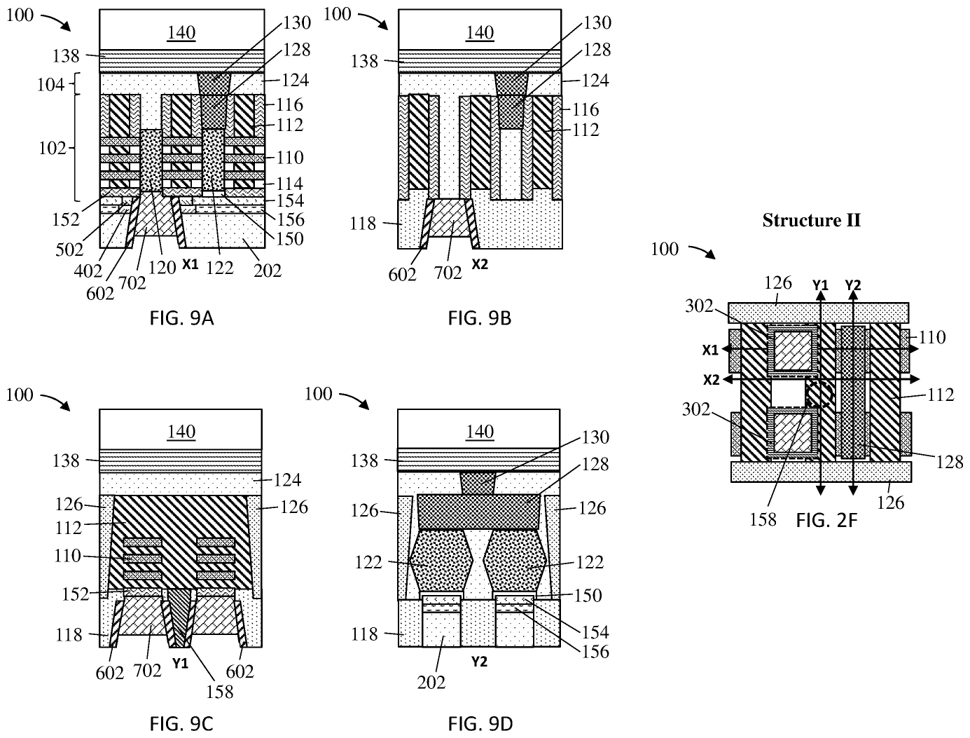

FIGS. 8A, 8B, 8C, and 8D, depict cross-sectional views of the semiconductor wafer 100 taken along the lines X1, X2, Y1, and Y2, respectively, of FIG. 1E after a processing operation according to one or more embodiments. The semiconductor wafer 100 is shown in FIGS. 8A, 8B, 8C, and 8D following the processing operations discussed with respect to FIGS. 7A, 7B, 7C, and 7D, and represents a first process option (“Structure I”). A second process option (“Structure II”) is described with respect to FIGS. 9A, 9B, 9C, and 9D.

As shown in FIG. 8C, the backside gate cap 158 can be removed and replaced with a backside gate contact 802. Notably, in some embodiments, the backside gate cap 158 can be removed using a selective pull with respect to the backside contact liner 602. The backside gate cap 158 can then be replaced using known contact metallization processes.

In some embodiments, a backside power rail 804 (sometimes referred to as a BSPR) and a backside power delivery network 806 (sometimes referred to as a BSPDN) can be formed over the semiconductor wafer 100 (with respect to a post-flip orientation, omitted for clarity). The backside power delivery network 806 can include any number of conductive/metal layers, lines, and vias, and can be formed in a similar manner as the BEOL structures discussed previously, except that the backside power delivery network 806 is formed on an opposite side of the semiconductor wafer 100.

In some embodiments, an additional backside dielectric 808 is formed prior to the backside power rail 804 and the backside power delivery network 806. The additional backside dielectric 808 can be formed of similar materials and in a similar manner as the backside dielectric 202.

In some embodiments, a signal rail 810 is formed prior to the backside power delivery network 806. In some embodiments, the signal rail 810 couples the backside gate contact 802 to the backside power delivery network 806.

FIGS. 9A, 9B, 9C, and 9D, depict cross-sectional views of the semiconductor wafer 100 taken along the lines X1, X2, Y1, and Y2, respectively, of FIG. 1E after a processing operation according to one or more embodiments. The semiconductor wafer 100 is shown in FIGS. 9A, 9B, 9C, and 9D following the processing operations discussed with respect to FIGS. 7A, 7B, 7C, and 7D, and represents a second process option (“Structure II”). As shown in FIGS. 9A, 9B, and 9C, the one or more backside S/D contacts 702 are recessed to expose sidewalls of the backside contact liner 602.

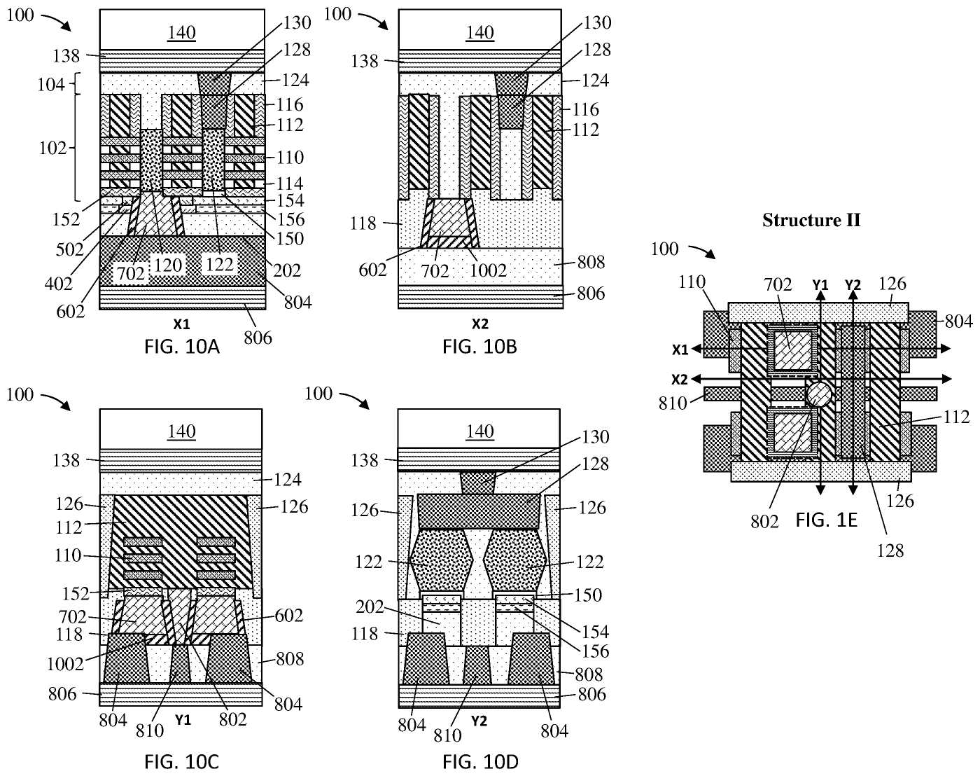

FIGS. 10A, 10B, 10C, and 10D, depict cross-sectional views of the semiconductor wafer 100 taken along the lines X1, X2, Y1, and Y2, respectively, of FIG. 1E after a processing operation according to one or more embodiments. As shown in FIGS. 10B and 10C, a backside S/D cap 1002 is formed over the recessed surface of the one or more backside S/D contacts 702. The backside S/D cap 1002 can be formed of similar materials and in a similar manner as the backside contact liner 602.

As shown in FIG. 10C, the backside gate cap 158 can be removed and replaced with a backside gate contact 802. Notably, in some embodiments, the backside gate cap 158 can be removed using a selective pull with respect to the backside contact liner 602 and/or the backside S/D cap 1002. The backside gate cap 158 can then be replaced using known contact metallization processes.

In some embodiments, a backside power rail 804, a backside power delivery network 806, an additional backside dielectric 808, and/or a signal rail 810 can then be formed in a similar manner as described with respect to Structure I (refer to FIGS. 8A to 8D), except that the backside S/D cap 1002 can prevent signal line wire shorts to the backside S/D contacts 702 even if misaligned (within the tolerance afforded by the backside S/D cap 1002).

After backside processing is complete, the semiconductor wafer 100 can be finalized using known processes (e.g., additional BEOL, far back end of line (FBEOL), packaging, etc., processes used to define a final device, including the incorporation of additional frontside and/or backside metallization layers).

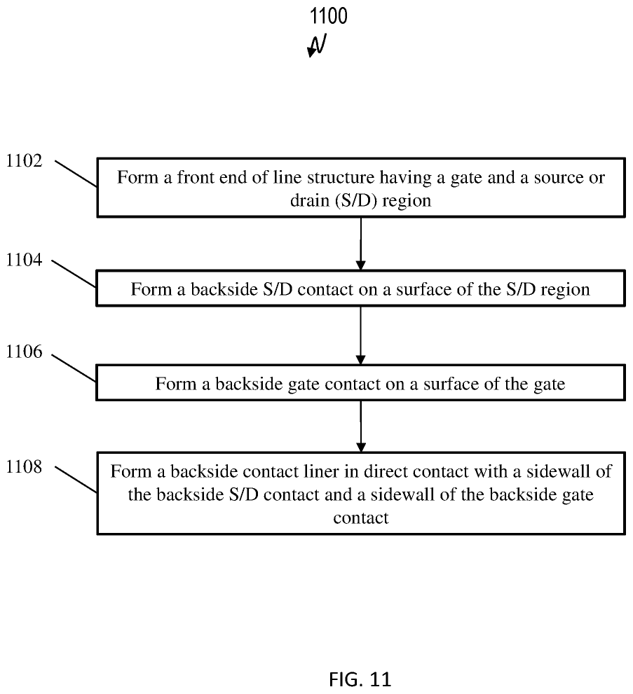

FIG. 11 depicts a flow diagram illustrating a method 1100 for providing contacts for gate, source, and drain regions through a wafer backside according to one or more embodiments of the invention. As shown at block 1102, the method includes forming a front end of line structure that includes a gate and a S/D region.

At block 1104, the method includes forming a backside S/D contact on a surface of the S/D region.

At block 1106, the method includes forming a backside gate contact on a surface of the gate.

At block 1108, the method includes forming a backside contact liner in direct contact with a sidewall of the backside S/D contact and a sidewall of the backside gate contact. In some embodiments, the backside gate contact is electrically isolated from the backside S/D contact by the backside contact liner.

In some embodiments, the backside contact liner is conformally formed on sidewalls of a backside S/D contact trench. In some embodiments, the backside contact liner is formed by conformally depositing dielectric liner material into a trench and breaking through. In some embodiments, breaking through includes removing a portion of the backside contact liner to expose a surface of a bottom dielectric isolation

In some embodiments, the method includes forming a backside power delivery network over the backside S/D contact and the backside gate contact. In some embodiments, the method includes forming a backside power rail between the backside power delivery network and the backside S/D contact. In some embodiments, the method includes forming a signal rail between the backside power delivery network and the backside gate contact.

Other structures are possible. For example, in some embodiments, a method includes forming a front end of line structure having a gate and a S/D region and forming a back end of line structure on a first surface of the front end of line structure. The back end of line structure includes a backside S/D contact on a surface of the S/D region, a backside S/D cap on a surface of the backside S/D contact opposite the S/D region, a backside power rail on the surface of the backside S/D contact, a backside gate contact on a surface of the gate, and a backside signal rail on the backside gate contact. In some embodiments, the backside power rail is electrically isolated from the backside gate contact and the backside signal rail by the backside S/D cap.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The phrase “selective to,” such as, for example, “a first element selective to a second element,” means that the first element can be etched and the second element can act as an etch stop (i.e., the second element remains).

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a<100>orientated crystalline surface can take on a<100>orientation. In some embodiments of the invention of the invention, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a semiconductor device, the method comprising:
forming a front end of line structure comprising a gate and a source or drain (S/D) region;
forming a backside S/D contact on a surface of the S/D region;
forming a backside gate contact on a surface of the gate; and
forming a backside contact liner in direct contact with a sidewall of the backside S/D contact and a sidewall of the backside gate contact.

2. The method of claim 1, wherein the backside gate contact is electrically isolated from the backside S/D contact by the backside contact liner.

3. The method of claim 1, wherein the backside contact liner is conformally formed on sidewalls of a backside S/D contact trench.

4. The method of claim 1, further comprising forming a backside power delivery network over the backside S/D contact and the backside gate contact.

5. The method of claim 4, further comprising forming a backside power rail between the backside power delivery network and the backside S/D contact.

6. The method of claim 4, further comprising forming a signal rail between the backside power delivery network and the backside gate contact.

7. The method of claim 1, wherein the backside contact liner is formed by conformally depositing dielectric liner material into a trench and breaking through.

8. The method of claim 7, wherein breaking through comprises removing a portion of the backside contact liner to expose a surface of a bottom dielectric isolation.

9. A semiconductor device comprising:
a front end of line structure comprising a gate and a source or drain (S/D) region, the front end of line structure further comprising a first buffer layer and a second buffer layer below a bottom dielectric layer (BDI); and
a back end of line structure on a first surface of the front end of line structure, the back end of line structure comprising:
a backside S/D contact on a surface of the S/D region;
a backside gate contact on a surface of the gate; and
a backside contact liner in direct contact with a sidewall of the backside S/D contact and a sidewall of the backside gate contact.

10. The semiconductor device of claim 9, wherein the backside gate contact is electrically isolated from the backside S/D contact by the backside contact liner.

11. The semiconductor device of claim 9, further comprising a first backside inner spacer embedded into the first buffer layer and a second backside inner spacer embedded into the second buffer layer, wherein the backside contact liner is in direct contact with a sidewall of the first backside inner spacer and a sidewall of the second backside inner spacer.

12. The semiconductor device of claim 9, further comprising a backside power delivery network over the backside S/D contact and the backside gate contact.

13. The semiconductor device of claim 12, further comprising a backside power rail between the backside power delivery network and the backside S/D contact.

14. The semiconductor device of claim 12, further comprising a signal rail between the backside power delivery network and the backside gate contact.

15. A semiconductor device comprising:
a front end of line structure comprising a gate and a source or drain (S/D) region, the front end of line structure further comprising a first buffer layer and a second buffer layer below a bottom dielectric layer (BDI); and
a back end of line structure on a first surface of the front end of line structure, the back end of line structure comprising:
a backside S/D contact on a surface of the S/D region;
a backside S/D cap on a surface of the backside S/D contact opposite the S/D region;
a backside power rail on the surface of the backside S/D contact;
a backside gate contact on a surface of the gate; and
a backside signal rail on the backside gate contact.

16. The semiconductor device of claim 15, wherein the backside power rail is electrically isolated from the backside gate contact and the backside signal rail by the backside S/D cap.

17. The semiconductor device of claim 15, further comprising a backside contact liner in direct contact with a sidewall of the backside S/D contact and a sidewall of the backside gate contact.

18. The semiconductor device of claim 17, wherein the backside contact liner is conformally formed on sidewalls of a backside S/D contact trench.

19. The semiconductor device of claim 17, further comprising a backside inner spacer on a sidewall of the backside contact liner.

20. The semiconductor device of claim 15, further comprising a backside power delivery network on the backside power rail and the backside signal rail.
